(19) United States
(12) Patent Application Publication
(10) Pub. No.: US 2021/0149305 A1
(43) Pub. Date: May 20, 2021

(54) PHOTOSENSITIVE RESIN COMPOSITION AND INSULATING LAYER PREPARED THEREFROM

(71) Applicant: ROHM AND HAAS ELECTRONIC MATERIALS KOREA LTD., Chungcheongnam-do (KR)

(72) Inventors: Su Min Lee, Gyeonggi-do (KR); Jin Kwon, Gyeonggi-do (KR); Ho-Suk Song, Gyeonggi-do (KR)

(21) Appl. No.: 17/084,195

(22) Filed: Oct. 29, 2020

(30) Foreign Application Priority Data
Nov. 19, 2019 (KR) 10-2019-0148725

(51) Int. Cl. G03F 7/085; G03F 7/033; G03F 7/004

(52) U.S. Cl. CPC G03F 7/085; G03F 7/0048; G03F 7/033

(57) ABSTRACT

The present invention relates to a photosensitive resin composition and an insulation film prepared therefrom. Since the photosensitive resin composition comprises a blocked isocyanate-based compound, it can form a transparent insulation film while it maintains excellent film retention rate, hardness, and resolution.

### TECHNICAL FIELD

The present invention relates to a photosensitive resin composition capable of forming an insulation film having excellent film retention rate, hardness, resolution, and transmittance, and an insulation film prepared therefrom.

### BACKGROUND ART

In recent years, displays having a touch screen panel (TSP) have been actively developed in the display industry. A TSP is suitable for miniaturized and large-sized devices, but it must have such physical properties as high durability, precise response to touch, and excellent optical properties.

In general, a light emitting member (LCD or OLED) as an upper member of a display is fabricated, followed by the fabrication of a TSP. In such event, an insulation film is required between the metal electrodes in the TSP. In order to minimize the effect on the light emitting member, which has already been fabricated, the insulation film applied to the TSP must be thermally cured at a temperature lower than that for conventional insulation films. Thus, a low curing temperature is required.

Conventionally, a composition for an organic protective film capable of being cured at a temperature of120° C. or lower has been known, which uses an acrylic copolymer obtained by polymerizing a methacrylate-based compound with an olefinic compound (see Korean Laid-open Patent Publication No. 2008-0102838). However, the proportion of carboxyl groups (acid groups) in the composition is lower as the functional groups (photopolymerizable functional groups) of the methacrylate-based compound are more introduced into the olefinic compound. Thus, the composition has a disadvantage in that it does not sufficiently satisfy the photosensitivity, whereby it is not appropriate for application to an insulation film of a TSP.

In addition, since the insulation film is required to have high transmittance and adhesion to the metal of a TSP, it normally comprises an adhesion promoter or an adhesion aid.

Such an adhesion promoter generally contains an organic group and an inorganic group, in which the organic group of the adhesion promoter causes a chemical reaction with the photosensitive resin composition so that the photosensitive resin composition can be chemically bonded to the underlying film.

However, the isocyanate-based compounds widely used as an adhesion promoter are preferably applied to a photosensitive resin composition that requires low-temperature curing, whereas they have a disadvantage in that it reduces the transparency by reaction with other components. Thus, they are limitedly applied to black compositions, light shielding films, and light shielding layers (see Korean Laid-open Patent Publication No. 2015-0008759),

### DETAILED DESCRIPTION OF THE INVENTION

### Technical Problem

Accordingly, the present invention aims to provide a photosensitive resin composition capable of being cured at a low temperature by using a blocked isocyanate compound and, at the same time, capable of enhancing the adhesion with an underlying film and forming a transparent insulation film, and an insulation film prepared therefrom.

### Solution to the Problem

In order to achieve the above object, the present invention provides a photosensitive resin composition, which comprises (A) a copolymer; (B) a photopolymerizable compound; (C) a photopolymerization initiator; (D) a blocked isocyanate-based compound; and (E) a solvent, wherein the blocking agent is dissociated from the blocked isocyanate-based compound (D) at 100° C. to 150° C.

In order to achieve another object, the present invention provides an insulation film prepared from the photosensitive resin composition.

### Advantageous Effects of the Invention

Since the photosensitive resin composition of the present invention comprises a blocked isocyanate-based compound, it can form a transparent insulation film while it maintains excellent film retention rate, hardness, and resolution.

### BEST MODE FOR CARRYING OUT THE INVENTION

The present invention is not limited to those described below. Rather, it can be modified into various forms as long as the gist of the invention is not altered.

Throughout the present specification, when a part is referred to as “comprising” an element, it is understood that other elements may be comprised, rather than other elements are excluded, unless specifically stated otherwise. in addition, all numbers and expressions relating to quantities of components, reaction conditions, and the like used herein are to be understood as being modified by the term “about” unless specifically stated otherwise.

The present invention provides a photosensitive resin composition, which comprises (A) a copolymer; (B) a photopolymerizable compound; (C) a photopolymerization initiator; (D) a blocked isocyanate-based compound; and (E) a solvent. Here, the blocking agent is dissociated from the blocked isocyanate-based compound (D) at 100° C. to 150° C.

The composition may optionally further comprise (F) a surfactant; and/or (G) a silane coupling agent.

As used herein, the term “(meth)acryl” refers to “acryl” and/or “methacryl,” and the term “(meth)acrylate” refers to “acrylate” and/or “methacrylate.”

The weight average molecular weight (g/mole or Da) of each component as described below is measured by gel permeation chromatography (GPC, eluent: tetrahydrofuran) referenced to a polystyrene standard.

(A) Copolymer

The photosensitive resin composition according to the present invention may comprise a copolymer (A) as a binder as described below.

The copolymer may comprise (a1) a structural unit derived from an ethylenically unsaturated carboxylic acid, an ethylenically unsaturated carboxylic anhydride, or a combination thereof; (a2) a structural unit derived from an ethylenically unsaturated compound containing an epoxy group; and (a3) a structural unit derived from an ethylenically unsaturated compound different from (a1) and (a2).

(a1) Structural Unit Derived from an Ethylenically Unsaturated Carboxylic Acid, an Ethylenically Unsaturated Carboxylic Anhydride, or a Combination Thereof

The structural unit (a1) in the present invention may be derived from an ethylenically unsaturated carboxylic acid, an ethylenically unsaturated carboxylic anhydride, or a combination thereof.

The ethylenically unsaturated carboxylic acid, the ethylenically unsaturated carboxylic anhydride, or a combination thereof is a polymerizable unsaturated compound containing at least one carboxyl group in the molecule. It may be at least one selected from an unsaturated monocarboxylic acid such as (meth)acrylic acid, crotonic acid, α-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid having three or more valences and an anhydride thereof; and a mono[(meth)acryloyloxyalkyl]ester of a polycarboxylic acid of divalence or more such as mono[2-(meth)acryloyloxyethyl]succinate, mono[2-(meth)acryloyloxyethyl]phthalate, and the like. But it is not limited thereto. It may be preferably (meth)acrylic acid among them particularly from the viewpoint of developability.

The content of the structural unit (a1) derived from an ethylenically unsaturated carboxylic acid, an ethylenically unsaturated carboxylic anhydride, or a combination thereof may range from 5% by weight to 50% by weight, 10% by weight to 40% by weight, or 15% by weight to 35% by weight, based on the total number of moles of the structural units constituting the copolymer (A). Within the above range, it is possible to attain a pattern formation of a film while maintaining favorable developability.

(a2) Structural Unit Derived from an Ethylenically Unsaturated Compound Containing an Epoxy Group

The structural unit (a2) in the present invention may be derived from an ethylenically unsaturated compound containing an epoxy group.

Specifically, the structural unit (a2) may comprise (a2-1) a structural unit derived from an unsaturated monomer containing an alicyclic epoxy group represented by the following Formula 2; and (a2-2) a structural unit derived from an unsaturated monomer containing an acyclic epoxy group represented by the following Formula 3.

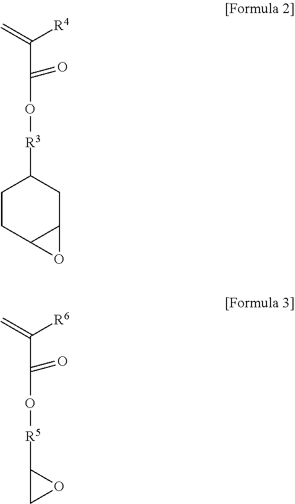

In the above formulae, R⁴ and R⁶ are each independently hydrogen or C₁₋₄ alkyl, and R³ and R⁵ are each independently C₁₋₄ alkylene. More specifically, R⁴ and R⁶ may be each independently hydrogen or methyl, and R³ and R₅ may be C₁₋₄ alkylene.

The unsaturated monomer (a2-1) containing an alicyclic epoxy group may be 3,4-epoxycyclohexylmethyl acrylate or 3,4-epoxycyclohexylmethyl methacrylate. The unsaturated monomer (a2-2) containing an acyclic epoxy group may be glycidyl acrylate or glycidyl methacrylate.

The total content of the structural units (a2-1) and (a2-2) may range from 10% by mole to 50% by mole, 10% by mole to 45% by mole, 10% by mole to 40% by mole, 10% by mole to 30% by mole, 10% by mole to 20% by mole, 15% by mole to 50% by mole, 15% by mole to 45% by mole, 15% by mole to 40% by mole, 15% by mole to 30% by mole, or 15% by mole to 20% by mole, based on the total number of moles of the structural units of the copolymer (A). Within the above range, the storage stability of the composition is maintained, and the film retention rate is enhanced.

In addition, the molar ratio of the structural units (a2-1) and (a2-2) is 50 to 99:50 to 1, 50 to 90:50 to 10, 50 to 85:50 to 15, 50 to 80:50 to 20, or 50 to 75:50 to 25. Within the above range, it is possible to achieve excellent stability over time at room temperature, thermal resistance, and chemical resistance, and the pattern formation is enhanced.

(a3) Structural Unit Derived from an Ethylenically Unsaturated Compound Different from (a1) and (a2)

The structural unit (a3) in the present invention may be derived from an ethylenically unsaturated compound different from the structural units (a1) and (a2).

Specifically, the structural unit (a3) may be at least one selected from the group consisting of an ethylenically unsaturated compound having an aromatic ring such as phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate, styrene, methylstyrene, dimethylstyrene, trimethylstyrene, ethylstyrene, diethylstyrene, triethylstyrene, propylstyrene, butylstyrene, hexylstyrene, heptylstyrene, octylstyrene, fluorostyrene, chlorostyrene, bromostyrene, iodostyrene, methoxystyrene, ethoxystyrene, propoxystyrene, p-hydroxy-α-methylstyrene, acetylstyrene, vinyl toluene, divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; an N-vinyl tertiary amine containing an N-vinyl group such as N-vinyl pyrrolidone, N-vinyl carbazole, and N-vinyl morpholine; an unsaturated ether such as vinyl methyl ether and vinyl ethyl ether; and an unsaturated imide such as N-phenylmaleimide, N-(4-chlorophenyl)maleimide, N-(4-hydroxyphenyl)maleimide, and N-cyclohexylmaleimide.

The total content of the structural unit (a3) may range from 5% by mole to 70% by mole, 5% by mole to 65% by mole, 10% by mole to 70% by mole, 10% by mole to 65% by mole, 10% by mole to 60% by mole, 20% by mole to 65% by mole, 20% by mole to 55% by mole, 30% by mole to 65% by mole, 30% by mole to 60% by mole, 30% by mole to 55% by mole, 40% by mole to 65% by mole, 40% by mole to 60% by mole, 40% by mole to 55% by mole, or 40% by mole to 50% by mole, based on the total number of moles of the structural units of the copolymer (A). Within the above range, it is possible to control the reactivity of the copolymer (A) and to increase the solubility thereof so that the coatability of the photosensitive resin composition is remarkably enhanced.

The copolymer (A) used in the present invention may have a weight average molecular weight of 500 Da to 50,000 Da, preferably 3,000 Da to 30,000 Da. If it has a weight average molecular weight within the above range_{;} the adhesion to a substrate is excellent, the physical and chemical properties are favorable, and the viscosity is proper.

The copolymer (A) used in the present invention may be synthesized by copolymerization known in the art. The content of the copolymer (A) may range from 1% by weight to 80% by weight, 5% by weight to 80% by weight, 5% by weight to 70% by weight, 5% by weight to 60% by weight, 10% by weight to 80% by weight, 10% by weight to 70% by weight, 10% by weight to 60% by weight, 20% by weight to 80% by weight, 20% by weight to 70% by weight, 20% by weight to 60% by weight, 30% by weight to 80% by weight, 30% by weight to 70% by weight, 30% by weight to 60% by weight, 40% by weight to 80% by weight, 40% by weight to 70% by weight, 40% by weight to 60% by weight, 50% by weight to 80% by weight, 50% by weight to 70% by weight, or 50% by weight to 60% by weight, based on the total weight of the photosensitive resin composition excluding the balanced amount of solvents. Within the above range, a pattern profile after development is favorable, and such properties as film retention rate and chemical resistance are enhanced.

(B) Photopolymerizable Compound

The photopolymerizable compound (or monomer) employed in the present invention is a compound that is polymerizable by the action of a photopolymerization initiator. It may include a monofunctional or multifunctional ester compound of acrylic acid or methacrylic acid having at least one ethylenically unsaturated group. It may preferably be a multifunctional compound having at least two functional groups from the viewpoint of chemical resistance.

The polymerizable compound may be at least one selected from the group consisting of ethylene glycol di(meth)acrylate, propylene glycol di(meth)acrylate, diethylene glycol di(meth)acrylate, triethylene glycol di(meth)acrylate, 1,6-hexanediol di(meth)acryl ate, polyethylene glycol di(meth)acrylate, polypropylene glycol di(meth)acrylate, glycerin tri(meth)acrylate, trimethylolpropane tri(meth)acrylate, pentaerythritol tri(meth)acrylate, a monoester of pentaerythritol tri(meth)acrylate and succinic acid, pentaerythritol tetra(meth)acrylate, dipentaerythritol penta(meth)acrylate, dipentaerythritol hexa(meth)acrylate, a monoester of dipentaerythritol penta(meth)acrylate and succinic acid, caprolactone modified dipentaerythritol hexa(meth)acrylate, pentaerythritol triacrylate-hexamethylene diisocyanate (a reaction product of pentaerythritol triacrylate and hexamethylene diisocyanate), tripentaerythritol hepta(meth)acrylate, tripentaerythritol octa(meth)acrylate, bisphenol A epoxyacrylate, and ethylene glycol monomethyl ether acrylate, but it is not limited thereto.

In addition, it may include a multifunctional urethane acrylate compound obtained by reacting a compound having a straight-chain alkylene group and an alicyclic structure with two or more isocyanate groups and a compound having one or more hydroxyl groups and three, four, or five acryloyloxy groups and/or methacryloyloxy groups in the molecule, but it is not limited thereto.

Examples of the photopolymerizable compound commercially available may include a monofunctional (meth)acrylate such as Aronix M-101, M-111, and M-114 manufactured by Toagosei Co., Ltd., KAYARAD TC-110S and TC-120S manufactured by Nippon Kayaku Co., Ltd., and V-158 and V-2311 manufactured by Osaka Yuki Kagaku Kogyo Co., Ltd.; a bifunctional (meth)acrylate such as Aronix M-210, M-240, and M-6200 manufactured by Toagosei Co., Ltd., KAYARAD HDDA, HX-220, and R-604 manufactured by Nippon Kayaku Co., Ltd., and V-260, V-312, and V-335 HP manufactured by Osaka Yuki Kagaku Kogyo Co., Ltd.; and a tri- and higher functional (meth)acrylate such as Aronix M-309, M-400, M-403, M-405, M-450, M-7100, M-8030, M-8060, and TO-1382 manufactured by Toagosei Co., Ltd., KAYARAD TMPTA, DPHA, DPHA-40H, DPCA-20, DPCA-30, DPCA-60, and DPCA-120 manufactured by Nippon Kayaku Co., Ltd., and V-295, V-300, V-360, V-GPT, V-3PA and V-400 manufactured by Osaka Yuki Kagaku Kogyo Co., Ltd.

The photopolymerizable compounds may be used alone or in combination of two or more thereof. It may be employed in an amount of 1 part by weight to 100 parts by weight, 10 parts by weight to 80 parts by weight, 20 parts by weight to 80 parts by weight, 20 parts by weight to 70 parts by weight, 30 parts by weight to 80 parts by weight, 30 parts by weight to 70 parts by weight, 40 parts by weight to 80 parts by weight, 40 parts by weight to 70 parts by weight, 50 parts by weight to 80 parts by weight, or 50 parts by weight to 70 parts by weight, based on 100 parts by weight of the copolymer (A) (based on the solids content). Within the above range, it is possible to achieve high sensitivity with an excellent pattern developability and film characteristics.

(C) Photopolymerization Initiator

The photopolymerization initiator employed in the present invention serves to initiate the polymerization of monomers that can be cured by visible light, ultraviolet radiation, deep-ultraviolet radiation, or the like.

The photopolymerization initiator may be a radical initiator. Examples thereof include at least one selected from the group consisting of an acetophenone-based, benzophenone-based, benzoin-based, benzoyl-based, xanthone-based, triazine-based, halomethyloxadiazole-based, and rofindimer-based photopolymerization initiators, but it is not limited thereto.

Particular examples thereof may include 2,2′-azobis(2,4-dimethylvaleronitrile), 2,2′-azobis(4-methoxy-2,4-dimethylvaleronitrile), benzoyl peroxide, lauryl peroxide, t-butyl peroxy pivalate, 1,1-bis(t-butylperoxy)cyclohexane, p-dimethylaminoacetophenone, 2-benzyl-2-(dimethylamino)-1-[4-(4-morpholinyl)phenyl]-1-butanone, 2-hydroxy-2-methyl-1-phenyl-propan-1-one, benzyl dimethyl ketal, benzophenone, benzoin propyl ether, diethyl thioxanthene, 2,4-bis (trichloromethyl)-6-p-methoxyphenyl-s-triazine, 2-trichloromethyl-5-styryl-1,3,4-oxodiazole, 9-phenylacridine, 3-methyl-5-amino-((s-triazin-2-yl)amino)-3-phenylcoumarin, 2-(o-chlorophenyl)-4,5-diphenylimidazolyl dimer, 1-phenyl-1,2-propanedione-2-(o-ethoxycarbonyl)oxime, 1-[4-(phenylthio)phenyl]-octane-1,2-dione-2-(o-benzoyloxime), o-benzoyl-4′-(benzmercapto)benzoylhexylketoxime, 2,4,6-trimethylphenylcarbonyl-diphenylphosphonyloxide, a hexafluorophosphoro-trialkylphenylsulfonium salt, 2-mercaptobenzimidazole, 2,2′-benzothiazolyl disulfide, and a mixture thereof, but is not limited thereto. In addition, the oxime-based compounds disclosed in KR 2004-0007700, KR 2005-0084149, KR 2008-0083650, KR 2008-0080208, KR 2007-0044062, KR 2007-0091110, KR 2007-0044753, KR 2009-0009991, KR 2009-0093933, KR 2010-0097658, KR 20111-0059525, WO 10102502, and WO 10133077 may be used.

The photopolymerization initiator may be employed in an amount of 0.1 part by weight to 20 parts by weight, 0.1 part by weight to 15 parts by weight, 1 part by weight to 20 parts by weight, 1 part by weight to 15 parts by weight, 1 part by weight to 10 parts by weight, 1 part by weight to 8 parts by weight, 1 part by weight to 6 parts by weight, 1 part by weight to 5 parts by weight, 2 parts by weight to 10 parts by weight, 2 parts by weight to 8 parts by weight, 2 parts by weight to 6 parts by weight, or 2 parts by weight to 5 parts by weight, based on 100 parts by weight of the copolymer (A) (based on the solids content). Within the above range, it is possible to achieve high sensitivity with an excellent pattern developability and film characteristics.

(D) Blocked Isocyanate-Based Compound

The blocked isocyanate-based compound employed in the present invention may be in the form in which a blocking agent is bonded to the —NCO group of an isocyanate.

The —NCO group has high reactivity to readily react with compounds having an active hydrogen, such as a hydroxyl group, an amine group, a carboxyl group, an epoxy group, water, acids, and the like. The crosslinking reaction through such a reaction can further enhance the adhesion between the insulation film and the substrate.

If a photosensitive resin composition comprises an isocyanate compound not bonded with a blocking agent, the —NCO group of the isocyanate, when mixed with other components, reacts with such components as the copolymer (A) and the solvent (E) to form a polymer having a color, whereby a transparent composition cannot be obtained.

Thus, a blocked isocyanate-based compound as described below is employed in the present invention. The blocked isocyanate-based compound may be a compound represented by the following Formula 1.

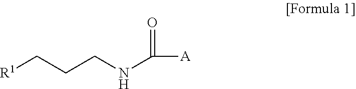

In the above formula, R¹ is hydrogen, C₁₋₂₀ alkyl, C₁₋₂₀ alkoxy, or Si(R²)₃, R² is each independently C₁₋₂₀ alkyl or C₁₋₂₀ alkoxy, and A is 3- to 10-membered heteroaryl containing one or more heteroatoms, which are the same or different and selected from the group consisting of N, O, and S, wherein the heteroaryl may be unsubstituted or substituted with C₁₋₁₀ alkyl or C₁₋₁₀ alkoxy.

Specifically, R¹ is C₁₋₂₀ alkyl or Si(R²)₃, R² is each independently C₁₋₂₀ alkoxy, and A is 4- to 6-membered heteroaryl containing one or more heteroatoms, which are the same or different and selected from the group consisting of N, O, and S, wherein the heteroaryl may be unsubstituted or substituted with C₁₋₁₀ alkyl or C₁₋₁₀ alkoxy.

More specifically, R¹ may be Si(EtO)₃, Si(MtO)₃, or methyl, and A may be

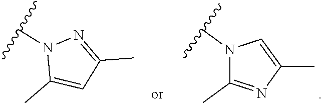

Here, A is a blocking agent, and the isocyanate before bonding with the blocking agent A may be 3-isocyanatopropyltrimethoxysilane, 3-isocyanatopropyltriethoxysilane, and the like.

The blocking agent may be dissociated at 100° C. to 150° C., 100° C. to 140° C., 110° C. to 130° C., 110° C. to 150° C., 120° C. to 150° C., or 120° C. to 140° C. Within the above range, the —NCO group of the isocyanate-based compound is blocked by the blocking agent during polymerization, so that a transparent insulation film can be obtained.

Specifically, the —NCO group of the isocyanate-based compound may react with hydroxyl groups, amine groups, carboxyl groups, epoxy groups, and the like contained in other components (e.g., binders, solvents, and the like) in the composition to form a colored polymer. In the present invention, however, the —NCO group of the isocyanate-based compound is blocked during polymerization, thereby suppressing the reaction of the —NCO group with other components, which prevents the formation of a polymer that exhibits a color. Thus, a transparent insulation film can be obtained.

The blocked isocyanate-based compound may be employed in an amount of 0.01 part by weight to 5 parts by weight, 0.01 part by weight to 3 parts by weight, 0,1 part by weight to 5 parts by weight, 0.1 part by weight to 3 parts by weight, 0.5 part by weight to 5 parts by weight, 0.5 part by weight to 3 parts by weight, 1 part by weight to 5 parts by weight, or 1 part by weight to 3 parts by weight, based on 100 parts by weight of the copolymer (A) (based on the solids content). Within the above range, the adhesion to a substrate can be further enhanced while the transparency of the insulation film is maintained.

(E) Solvent

The photosensitive resin composition of the present invention may be prepared as a liquid composition in which the above components are mixed with a solvent. In such event, the solvent may comprise a cyclic ketone-based compound.

Specifically, the cyclic ketone-based compound may be at least one selected from the group consisting of cyclohexanone, cyclopentanone, and cyclobutanone. It may preferably be cyclopentanone. The cyclic ketone-based compound may have a boiling point of 70° C. to 160° C., 90° C. to 150° C., or 120° C. to 140° C.

Meanwhile, the cyclic ketone-based compound may react with an isocyanate in the presence of an acid catalyst to form a chromophore. In the present invention, however, a transparent composition can be obtained by blocking the reactive group (i.e., —NCO group) of the isocyanate as described above.

In addition, other solvents may be further employed in the present invention as long as they are compatible with the components of the photosensitive resin composition as described above and they do not impair the effects of the present invention.

Examples of such solvents include ethylene glycol monoalkyl ether acetates such as ethylene glycol monomethyl ether acetate and ethylene glycol monoethyl ether acetate; propylene glycol monoalkyl ethers such as propylene glycol monomethyl ether, propylene glycol monoethyl ether, propylene glycol monopropyl ether, and propylene glycol monobutyl ether; propylene glycol dialkyl ethers such as propylene glycol dimethyl ether, propylene glycol diethyl ether, propylene glycol dipropyl ether, and propylene glycol dibutyl ether; dipropylene glycol dialkyl ethers such as dipropylene glycol dimethyl ether; propylene glycol monoalkyl ether acetates such as propylene glycol monomethyl ether acetate, propylene glycol monoethyl ether acetate, propylene glycol monopropyl ether acetate, and propylene glycol monobutyl ether acetate; cellosolves such as ethyl cellosolve and butyl cellosolve; carbitols such as butyl carbitol; lactic acid esters such as methyl lactic acid, ethyl lactic acid, n-propyl lactic acid, and isopropyl lactic acid; aliphatic carboxylic acid esters such as ethyl acetic acid, n-propyl acetic acid, isopropyl acetic acid, n-butyl acetic acid, isobutyl acetic acid, n-amyl acetic acid, isoamyl acetic acid, isopropyl propionic acid, n-butyl propionic acid, and isobutyl propionic acid; esters such as methyl 3-methoxypropionic acid, ethyl 3-methoxypropionic acid, methyl 3-ethoxypropionic acid, ethyl 3-ethoxypropionic acid, methyl pyruvic acid, and ethyl pyruvic acid; aromatic hydrocarbons such as toluene and xylene; ketones such as 2-heptanone, 3-heptanone, and 4-heptanone; amides such as N-dimethylformamide, N-methylacetamide, N,N-dimethylacetamide, and N-methylpyrrolidone; lactones such as γ-butyrolactone; and mixtures thereof, but they are not limited thereto. The solvent may be used alone or in combination of two or more,

In the photosensitive resin composition according to the present invention, the content of the solvent is not particularly limited, but the solvent may be employed such that the solids content is 5% by weight to 70% by weight, 5% by weight to 60% by weight, 10% by weight to 70% by weight, 10% by weight to 60% by weight, 10% by weight to 55% by weight, 10% by weight to 50% by weight, 10% by weight to 45% by weight, 10% by weight to 40% by weight, 10% by weight to :30% by weight, 20% by weight to 60% by weight, 20% by weight to 55% by weight, 20% by weight to 50% by weight, 20% by weight to 45% by weight, 20% by weight to 40% by weight, or 20% by weight to 30% by weight, based on the total weight of the composition, from the viewpoint of coatability and stability of the photosensitive resin composition thus prepared.

In addition, the solvent may comprise the cyclic ketone-based compound in an amount of 1% by weight to 100% by weight, or 5% by weight to 100% by weight, based on the total weight of the solvent.

Within the above range, the compatibility with other components in the photosensitive resin composition is favorable, and the storage stability even at room temperature or low temperatures is excellent. In addition, the solvent may remain in an appropriate amount at a soft bake temperature when an insulation film is formed (at the time of coating), so that it may assist in forming or leveling a coating film. Further, it may evaporate sufficiently at a temperature of 100° C. to 150° C. to form a coating film at the time of low-temperature curing.

In addition, the photosensitive resin composition of the present invention may further comprise other components to improve the characteristics thereof. For example, the other components may include a surfactant and/or a silane coupling agent (G).

(F) Surfactant

The photosensitive resin composition of the present invention, if necessary, may further comprise a surfactant in order to enhance the coatability and to prevent the generation of defects.

The kind of surfactant is not particularly limited. Preferably, it may include fluorine-based surfactants, silicone-based surfactants, non-ionic surfactants, and the like. Preferably, BYK-307 from BYK among the above may be employed from the viewpoint of dispersibility.

Examples of the surfactant may include fluorine- and silicone-based surfactants such as BM-1000 and BM-1100 supplied by BM CHEMIE Co., Ltd., Megapack F142 D, F172, F173, F183, F-470, F-471, F-475, F-482, and F-489 supplied by Dai Nippon Ink Chemical Kogyo Co., Ltd., Florad FC-135, FC-170 C, FC-430, and FC-431 supplied by Sumitomo 3M Ltd., Sufron S-112, S-113, S-131, S-141, S-145, S-382, SC-101, SC-102, SC-103, SC-104, SC-105, and SC-106 supplied by Asahi Glass Co., Ltd., Eftop EF301, 303, and 352 supplied by Shinakida Kasei Co., Ltd., SH-28 PA, SH-190, SH-193, SZ-6032, SF-8428, DC-57, and DC-190 supplied by Toray Silicone Co., Ltd., DC3PA, DC7PA, SH11PA, SH21PA, SH8400, FZ-2100, FZ-2110, FZ-2122, FZ-2222, and FZ-2233 supplied by Dow Corning Toray Silicone Co., Ltd., TSF-4440, TSF-4300, TSF-4445, TSF-4446, TSF-4460, and TSF-4452 supplied by GE Toshiba Silicones Co., Ltd., and BYK-333 and BYK-307 supplied by BYK Corporation; non-ionic surfactants such as polyoxyethylene alkyl ethers such as polyoxyethylene lauryl ether, polyoxyethylene stearyl ether, and polyoxyethylene oleyl ether; polyoxyethylene aryl ethers such as polyoxyethylene octylphenyl ether and polyoxyethylene nonylphenyl ether; and polyoxyethylene dialkyl esters such as polyoxyethylene dilaurate and polyoxyethylene distearate; and organosiloxane polymer KP341 (manufactured by Shin-Etsu Chemical Co., Ltd.), (meth)acrylate-based copolymer Polyflow No. 57 and 95 (manufactured by Kyoei Yuji Chemical Co., Ltd.), and the like. They may be used alone or in combination of two or more thereof.

The surfactant may be employed in an amount of 0.0001 part by weight to 5 parts by weight, 0.0001 part by weight to 3 parts by weight, 0.001 part by weight to 5 parts by weight, 0.001 part by weight to 3 parts by weight, 0.01 part by weight to 5 parts by weight, 0.01 part by weight to 3 parts by weight, 0.1 part by weight to 5 parts by weight, or 0.1 part by weight to 3 parts by weight, based on 100 parts by weight of the copolymer (A) (based on the solids content). Within the above range, the coating of the composition is smoothly carried out.

(G) Silane Coupling Agent

In order to enhance the adhesion to a substrate, the photosensitive resin composition of the present invention may further comprise a silane coupling agent having at least one reactive group selected from the group consisting of a carboxyl group, a (meth)acryloyl group, an amino group, a mercapto group, a vinyl group, and an epoxy group.

The kind of silane coupling agent is not particularly limited. It may be at least selected from the group consisting of trimethoxysilyl benzoic acid, γ-methacryloxypropyltrimethoxysilane, vinyltriacetoxysilane, vinyltrimethoxysilane, γ-glycidoxypropyitrimethoxysilane, γ-glycidoxypropyltriethoxysilane, and β-(3,4-epoxycyclohexyl)ethyltrimethoxysilane. Preferred is γ-glycidoxypropyltrimethoxysilane or γ-glycidoxypropyltriethoxysilane having an epoxy group, which is capable of enhancing the film retention rate and is excellent in the adhesion to a substrate. The silane coupling agent may be employed in an amount of 0.0001 part by weight to 5 parts by weight, 0.0001 part by weight to 3 parts by weight, 0.001 part by weight to 5 parts by weight, 0.001 part by weight to 3 parts by weight, 0.01 part by weight to 5 parts by weight, 0.01 part by weight to 3 parts by weight, 0.01 part by weight to 1 part by weight, 0.1 part by weight to 5 parts by weight, or 0.1 part by weight to 3 parts by weight, based on 100 parts by weight of the copolymer (A) (based on the solids content). Within the above range, the adhesion to a substrate is favorable.

In addition, the photosensitive resin composition of the present invention may further comprise other additives such as antioxidants and stabilizing agents as long as the physical properties of the photosensitive resin composition are not adversely affected.

The photosensitive resin composition of the present invention as described above can be cured at relatively low temperatures. Specifically, the curing temperature may be 100° C. to 150° C., 100° C. to 140° C., 110° C. to 130° C., or 120° C. to 130° C.

The present invention provides an insulation film (or a cured film) formed from the photosensitive resin composition.

The insulation film may be prepared by a method known in the art. For example, the photosensitive resin composition is coated on a substrate by a spin coating method, which is subjected to pre-bake at a temperature of 60° C. to 130° C. for 60 seconds to 130 seconds to remove solvents. It is then exposed to light using a photomask having a desired pattern and subjected to development using a developer (for example, a tetramethylammonium hydroxide (IMAM solution) to form a pattern on the coating layer. Thereafter, the patterned coating layer, if necessary, is subjected to post-bake at a temperature of 100° C. to 150° C. for 10 minutes to 5 hours to prepare a desired insulation film.

The exposure to light may be carried out at an exposure dose of 10 mJ/cm² to 100 mJ/cm² based on a wavelength of 365 nm in a wavelength band of 200 nm to 450 nm. According to the process of the present invention, it is possible to easily form a desired pattern from the viewpoint of the process.

The coating of the photosensitive resin composition onto a substrate may be carried out by a spin coating method, a slit coating method, a roll coating method, a screen printing method, an applicator method, or the like, in a desired thickness of, e.g., 2 μm to 25 μm. In addition, as a light source used for the exposure (irradiation), a low-pressure mercury lamp, a high-pressure mercury lamp, an extra high-pressure mercury lamp, a metal halide lamp, an argon gas laser, or the like may be used. X-ray, electronic ray, or the like may also be used, if desired.

The photosensitive resin composition of the present invention is capable of forming an insulation film that is excellent in terms of thermal resistance, transparency, dielectric constant, solvent resistance, acid resistance, and alkali resistance.

For example, the insulation film may have a transmittance of 90% or more, 93% or more, or 94% or more at a wavelength of 400 nm to 800 nm.

Specifically, the insulation film can maintain the excellent transmittance as described above even when stored for 1 day or more, 3 days or more, 7 days or more, or 1 to 7 days at a low temperature of 4° C. or lower or −17° C. to 4° C. and a high temperature of 35° C. or higher, 40° C. or higher, 35° C. to 50° C., 35° C. to 45° C., or 40° C. (see Evaluation Example 3).

Therefore, the insulation film of the present invention thus formed has excellent light transmittance devoid of surface roughness when it is subjected to thermal treatment or is immersed in, or comes into contact with, a solvent, an acid, a base, or the like. Thus, the cured film can be effectively used as a planarization film for a thin-film transistor (TET) substrate of a liquid crystal display or an organic EL display; a partition of an organic EL display; an interlayer dielectric of a semiconductor device; a core or cladding material of an optical waveguide, or the like.

### EMBODIMENTS FOR CARRYING OUT THE INVENTION

Hereinafter, the present invention will be described in more detail with reference to the following examples. However, these examples are provided to illustrate the present invention, and the scope of the present invention is not limited thereto only.

In the following preparation examples, the weight average molecular weight is determined by gel permeation chromatography (GPC, eluent: tetrahydrofuran) referenced to a polystyrene standard.

### Example

### Preparation Example 1: Preparation of a Copolymer (A)

A 500-ml, round-bottomed flask equipped with a refluxing condenser and a stirrer was charged with 40 g of a monomer mixture consisting of 50% by mole of styrene, 22% by mole of methacrylic acid, 10% by mole of glycidyl methacrylate, and 18% by mole of 3,4-epoxycyclohexylmethyl methacrylate, along with 120 g of methyl 3-methoxypropionate (MMP) as a solvent and 2 g of 2,2′-azobis(2,4-dimethylvaleronitrile) as a radical polymerization initiator. Thereafter, the temperature was raised to 70° C. with stirring for 8 hours to obtain a copolymer (A) solution having a solids content of 33% by weight. The copolymer (A) thus prepared had a weight average molecular weight of 7,000 Da.

### Examples and Comparative Examples: Preparation of Photosensitive Resin Compositions

The components used in the following Examples and Comparative Examples are as follows.

TABLE 1

| | | | Solids content | |
|---|---|---|---|---|
| Component | | | (% by weight) | Manufacturer |
| Copolymer (A) | | Preparation Example 1 | 33 | — |
| Photopolymerizable compound | | Dipentaerythritol hexaacrylate | 100 | Nippon |
| (B) | | (DPHA) | | Kayaku |
| Photopolymerization initiator | | OXE-02 | 100 | BASF |
| (C) | | | | |
| Blocked isocyanate | D-1 | X-12-1308ES | 100 | Shinetsu |
| compound (D) | D-2 | AH-3175KP | 100 | Aekyung |
| | | | | Chemical |
| Unblocked isocyanate | | 3-isocyanatopropyltriethoxysilane | 100 | Shinetsu |
| compound (D′) | | | | |
| Solvent (E) | E-1 | Cyclopentanone | — | Sigma |
| | | | | Aldrich |
| | E-2 | Cyclohexanone | — | Sigma |
| | | | | Aldrich |

| | | | |
|---|---|---|---|
| Surfactant (F) | BYK-307 | 100 | BYK |

### Example 1

100 parts by weight of the copolymer (A) prepared in Preparation Example 1, 66.7 parts by weight of a 6-functional dipentaerythritol hexaacrylate as a photopolymerizable compound, 5.3 parts by weight of OXE-02(C) as a photopolymerization initiator, 2.6 parts by weight of a blocked isocyanate-based (B1) compound (D-1), and 1.8 parts by weight of a surfactant (F) were mixed. Here, the respective contents are those based on the solids content exclusive of solvents. Thereafter, cyclopentanone (E-1) was added to the mixture such that the solids content of the mixture was 21% by weight. The resultant was mixed for 2 hours using a shaker to prepare a liquid-phase photosensitive resin composition.

### Examples 2 and 3 and Comparative Examples 1 and 2

Photosensitive resin compositions were each prepared in the same manner as in Example 1, except that the kinds and/or the contents of the respective components were changed as shown in Table 2 below.

TABLE 2

| | Copolymer | Photopolymerizable | Photopolymierization | B-Iso | | Iso | Surfactant | Solvent (E) | |
|---|---|---|---|---|---|---|---|---|---|
| | (A) | compound (B) | initiator (C) | D-1 | D-2 | D′ | (F) | E-1 | E-2 |
| Ex. 1 | 100 | 66.7 | 5.3 | 2.6 | — | — | 1.8 | 663.6 | — |
| Ex. 2 | 100 | 66.7 | 5.3 | — | 2.6 | — | 1.8 | 663.6 | — |
| Ex. 3 | 100 | 66.7 | 5 3 | 2.6 | — | — | 1.8 | — | 663.6 |
| C. Ex. 1 | 100 | 66.7 | 5.2 | — | — | 0.9 | 1.7 | 656.5 | — |
| C. Ex. 2 | 100 | 66.7 | 5.3 | — | — | 2.6 | 1.8 | 663.6 | — |

B-Iso: blocked isocyanate-based compound
Iso: Unblocked isocyanate-based compound

### Evaluation Example

Insulation films were each prepared from the photosensitive resin compositions obtained in Examples 1 to 3 and Comparative Examples 1 and 2. The film retention rate, pencil hardness, transmittance, and resolution of the insulation films were evaluated, and the results are shown in Table 3 below.

[Preparation of Insulation Films]

The photosensitive resin compositions obtained in the Examples and the Comparative Examples were each coated on a glass substrate using a spin coater and pre-baked at 100° C. for 60 seconds to form a coated film. A mask was placed on the coated film thus formed such that an area of 5 cm by 5 cm of the coated film was 100% exposed to light and that the gap with the substrate was maintained at 25 μm. Thereafter, the film was exposed to light at an exposure dose of 30 mJ/cm² based on a wavelength of 365 nm for a certain time period using an aligner (model name: MA6) that emits light having a wavelength of 200 nm to 450 nm. The exposed film was developed with an aqueous developer of 2.38% by weight of tetramethylammonium hydroxide (TMAH) at 23° C. until the unexposed portion was completely washed out. The exposed film on which the pattern was formed was heated (post-bake) in an oven at 130° C. for 1 hour to obtain an insulation film having a thickness of 2.5 μm.

### Evaluation Example 1: Film Retention Rate

The initial thickness upon the pre-bake was measured according to the process of preparing an insulation film. After the process of preparing the insulation film, the thickness upon development at 23° C. with an aqueous solution diluted to 2.38% by weight of TMAH was measured again. Finally, the thickness was measured upon the curing at 130° C. for 1 hour. The film retention rate was obtained by calculating the ratio in a percent of the thickness of the final insulation film to the thickness of the film upon the pre-bake.

### Evaluation Example 2: Pencil Hardness

An insulation film having a total thickness of 2.5 (±0.2) μm upon the final curing was prepared according to the process of preparing an insulation film. A weight of 500 g was applied using a pencil hardness tester in the same direction at a constant speed and angle (45°) to observe the degree of damage to the insulation film with a Mitsubishi UNI pencil from 6B to 9H.

### Evaluation Example 3: Transmittance (UV-vis)

A preliminary insulation film having a thickness of 2.5 μm was formed on a glass substrate according to the process of preparing an insulation film. The transmittance was measured after 7 days at −17° C. and 4° C., 3 days at room temperature, and 1 day at 40° C.

The transmittance was measured by scanning a wavelength region of 200 nm to 800 nm using an ultraviolet/visible light meter (Varian UV spectrometer) and measuring the transmittance of a wavelength band of 400 nm to 800 nm. The higher the average value of transmittance at a wavelength of 400 nm to 800 nm, the better.

### Evaluation Example 4: Resolution (Litho Performance)

The compositions prepared in the Examples and the Comparative Examples were each uniformly coated onto a glass substrate by spin coating, which was then dried on a hot plate kept at 100° C. for 1 minute to form a substrate. A negative mask having an opening pattern with a line width of 30 μm was placed on the substrate on which the dry film had been formed. it was then exposed to light at an exposure dose of 30 mJ/cm² using an aligner (model name: MA6) and developed with an aqueous developer solution diluted to 2.38% by weight of TMAH at 23° C. until the unexposed portion was completely washed out. Thereafter, the exposed film on which the pattern was formed was post-baked in an oven at 130° C. for 1 hour to obtain an insulation film having a thickness of 2.5 μm. For the substrate on which the insulation film was formed, the line width of the bottom of the pattern was measured with a non-contact type thickness meter (SIS-2000, SNU), and the resolution was evaluated according to the following criteria.

○: The bottom line was open in a width of 18 μm or more.

×: The bottom line was open in a width of less than 18 μm.

TABLE 3

| | | Transmittance | | | | | |
|---|---|---|---|---|---|---|---|
| | Film retention | 7 days at | 7 days at | 3 days at | 1 day at | Pencil | |
| | rate (%) | −17° C. | 4° C. | room temp. | 40° C. | hardness | Resolution |
| Ex. 1 | 81.3 | 99.8 | 99.0 | 99.0 | 94.9 | 1H | ∘ |
| Ex. 2 | 81.0 | 99.7 | 99.3 | 98.6 | 97.4 | 1H | ∘ |
| Ex. 3 | 82.0 | 99.6 | 99.3 | 98.9 | 98.3 | 1H | ∘ |
| C. Ex. 1 | 83.3 | 96.5 | 95.4 | 90.5 | 86.1 | 1H | ∘ |
| C. Ex. 2 | 85.9 | 97.4 | 93.2 | 88.9 | 80.3 | 1H | ∘ |

As can be seen from Table 3, the insulation films obtained from the compositions of the Examples, falling within the scope of the present invention, were overall excellent in film retention rate, pencil hardness, transmittance, and resolution. In contrast, the insulation films obtained from the compositions of Comparative Examples 1 and 2, falling outside the scope of the present invention, were poor in transmittance as compared with the insulation films prepared in the Examples.

1. A photosensitive resin composition, which comprises:
(A) a copolymer;
(B) a photopolymerizable compound;
(C) a photopolymerization initiator;
(D) a blocked isocyanate-based compound; and
(E) a solvent,
wherein the blocking agent is dissociated from the blocked isocyanate-based compound at 100° C. to 150° C.

2. The photosensitive resin composition of claim 1, wherein the blocked isocyanate-based compound (D) is a compound represented by the following Formula 1: 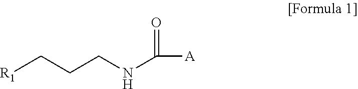
in the above formulae, R¹ is hydrogen, C₁₋₂₀ alkyl, C₁₋₂₀ alkoxy, or Si(R²)₃, R² is each independently C₁₋₂₀ alkyl or C₁₋₂₀ alkoxy, and A is 3- to 10-membered heteroaryl containing one or more heteroatoms, which are the same or different and selected from the group consisting of N, O, and S, wherein the heteroaryl may be unsubstituted or substituted with C₁₋₁₀ alkyl or C₁₋₁₀ alkoxy.

3. The photosensitive resin composition of claim 2, wherein R¹ is C₁₋₂₀ alkyl or Si(R²)₃, R² is each independently C₁₋₂₀ alkoxy, and A is 4- to 6-membered heteroaryl containing one or more heteroatoms, which are the same or different and selected from the group consisting of N, O, and S, wherein the heteroaryl may be unsubstituted or substituted with C₁₋₁₀ alkyl or C₁₋₁₀ alkoxy.

4. The photosensitive resin composition of claim 2, wherein R¹ is Si(EtO)₃, Si(MtO)₃, or methyl, and A is

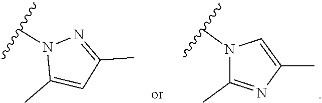

5. The photosensitive resin composition of claim 1, wherein the copolymer (A) comprises (a1) a structural unit derived from an ethylenically unsaturated carboxylic acid, an ethylenically unsaturated carboxylic anhydride, or a combination thereof; (a2) a structural unit derived from an ethylenically unsaturated compound containing an epoxy group; and (a3) a structural unit derived from an ethylenically unsaturated compound different from (a1) and (a2).

6. The photosensitive resin composition of claim 5, wherein the structural unit (a2) comprises (a2-1) a structural unit derived from an unsaturated monomer containing an alicyclic epoxy group represented by the following Formula 2; and (a2-2) a structural unit derived from an unsaturated monomer containing an acyclic epoxy group represented by the following Formula 3: 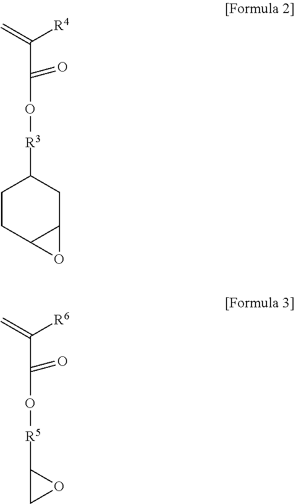
in the above formulae, R⁴ and R⁶ are each independently hydrogen or C₁₋₄ alkyl, and R³ and R⁵ are each independently C₁₋₄ alkylene.

7. The photosensitive resin composition of claim 6, wherein the total content of the structural units (a2-1) and (a2-2) ranges from 10% by mole to 50% by mole based on the total number of moles of the structural units of the copolymer (A).

8. The photosensitive resin composition of claim 6, wherein the molar ratio of the structural units (a2-1) and (a2-2) is 50 to 99:50 to 1.

9. The photosensitive resin composition of claim 1, wherein the solvent (E) comprises a cyclic ketone-based compound.

10. The photosensitive resin composition of claim 9, wherein the cyclic ketone-based compound is at least one selected from the group consisting of cyclohexanone, cyclopentanone, and cyclobutanone.

11. The photosensitive resin composition of claim 9, wherein the solvent (E) comprises the cyclic ketone-based compound in an amount of 5% by weight to 100% by weight based on the total weight of the solvent (E).

12. The photosensitive resin composition of claim 9, wherein the cyclic ketone-based compound has a boiling point of 70° C. to 160° C.

13. The photosensitive resin composition of claim 1, which has a curing temperature of 100° C. to 150° C.

14. An insulation film prepared from the photosensitive resin composition of claim 1.

15. The insulation film of claim 14, which has a transmittance of 90% or more at a wavelength of 400 nm to 800 nm.
